(19) United States
(12) Patent Application Publication
(10) Pub. No.: US 2016/0268532 A1
(43) Pub. Date: Sep. 15, 2016

(54) SOLAR CELL MODULE AND METHOD FOR MANUFACTURING THE SAME

(71) Applicant: Kabushiki Kaisha Toshiba, Minato-ku (JP)

(72) Inventors: Hideyuki NAKAO, Setagaya (JP); Haruhi OOOKA, Kawasaki (JP)

(73) Assignee: Kabushiki Kaisha Toshiba, Minato-ku (JP)

(21) Appl. No.: 15/063,624

(22) Filed: Mar. 8, 2016

(30) Foreign Application Priority Data
Mar. 9, 2015 (JP) 2015-046475

(51) Int. Cl. H01L 51/44; H01L 51/42

(52) U.S. Cl. CPC H01L 51/442; H01L 51/4253; H01L 51/424

(57) ABSTRACT

According to one embodiment, a solar cell module includes a substrate, a first upper electrode, a first lower electrode provided between the first upper electrode and the substrate, a lower intermediate layer including first to third lower regions, a first photoelectric conversion layer provided between the first upper electrode and the first lower electrode, a second upper electrode separated from the first upper electrode in a direction intersecting a first direction from the first lower electrode toward the first upper electrode, a second lower electrode provided between the second upper electrode and the substrate, and a second photoelectric conversion layer provided between the second upper electrode and the second lower electrode. The second upper electrode includes a first portion provided between the first photoelectric conversion layer and the second photoelectric conversion layer. The third lower region is disposed between the first portion and the substrate.

### CROSS-REFERENCE TO RELATED APPLICATIONS

This application is based upon and claims the benefit of priority from Japanese Patent Application No. 2015-046475, filed on Mar. 9, 2015; the entire contents of which are incorporated herein by reference.

### FIELD

Embodiments described herein generally relates to a solar cell module and a method for manufacturing a solar cell module.

### BACKGROUND

There are solar cells using organic semiconductors in which a conductive polymer and fullerene, etc. are combined. In solar cells using organic semiconductors, photoelectric conversion films may be formed by a simple way such as a coating method or a printing method. In solar cell modules using such solar cells, it is desirable to improve the appearance.

### BRIEF DESCRIPTION OF THE DRAWINGS

FIG. 1A and FIG. 1B are schematic cross-sectional views showing a solar cell module according to an embodiment;

FIG. 2 is a schematic cross-sectional view showing a portion of the solar cell module according to the embodiment;

FIG. 3A to FIG. 3C are schematic cross-sectional views showing the method for manufacturing the solar cell module according to the embodiment;

FIG. 4A to FIG. 4C are schematic cross-sectional views showing the method for manufacturing the solar cell module according to the embodiment;

FIG. 5 is a schematic plan view showing another solar cell module according to the embodiment;

FIG. 6 is a schematic plan view showing a photovoltaic power generation panel using the solar cell module according to the embodiment; and

FIG. 7A and FIG. 7B are schematic cross-sectional views showing another solar cell module according to the embodiment.

### DETAILED DESCRIPTION

According to one embodiment, a solar cell module includes a substrate, a first upper electrode, a first lower electrode, a lower intermediate layer, a first photoelectric conversion layer, a second upper electrode, a second lower electrode, a second photoelectric conversion layer. The first lower electrode is provided between the first upper electrode and the substrate. The first photoelectric conversion layer is provided between the first upper electrode and the first lower electrode. The first photoelectric conversion layer includes an organic semiconductor. The second upper electrode is separated from the first upper electrode in a direction intersecting a first direction. The first direction is from the first lower electrode toward the first upper electrode. The second lower electrode is provided between the second upper electrode and the substrate. The second photoelectric conversion layer is provided between the second upper electrode and the second lower electrode. The second photoelectric conversion layer includes an organic semiconductor. The second upper electrode includes a first portion provided between the first photoelectric conversion layer and the second photoelectric conversion layer in the direction intersecting the first direction. The lower intermediate layer includes a first lower region, a second lower region and a third lower region. The first lower region is disposed between the first photoelectric conversion layer and the first lower electrode. The second lower region is disposed between the second photoelectric conversion layer and the second lower electrode. The third lower region is disposed between the first portion and the substrate.

According to one embodiment, a method for manufacturing a solar cell module is disclosed. The method includes a lower electrode formation process of forming a first lower electrode and a second lower electrode on a substrate. The second lower electrode is separated from the first lower electrode. The method includes a lower intermediate layer formation process of forming a lower intermediate layer including a first lower region and a second lower region. The first lower region is formed on the first lower electrode and the second lower region is formed on the second lower electrode. The method includes a processing process of modifying a surface state of the first lower region and a surface state of the second lower region. The method includes a photoelectric conversion layer formation process of forming a first photoelectric conversion layer on the first lower region and forming a second photoelectric conversion layer on the second lower region. The first photoelectric conversion layer includes an organic semiconductor. The second photoelectric conversion layer includes an organic semiconductor. The method includes an upper electrode formation process of forming a first upper electrode on the first photoelectric conversion layer and forming a second upper electrode on the second photoelectric conversion layer.

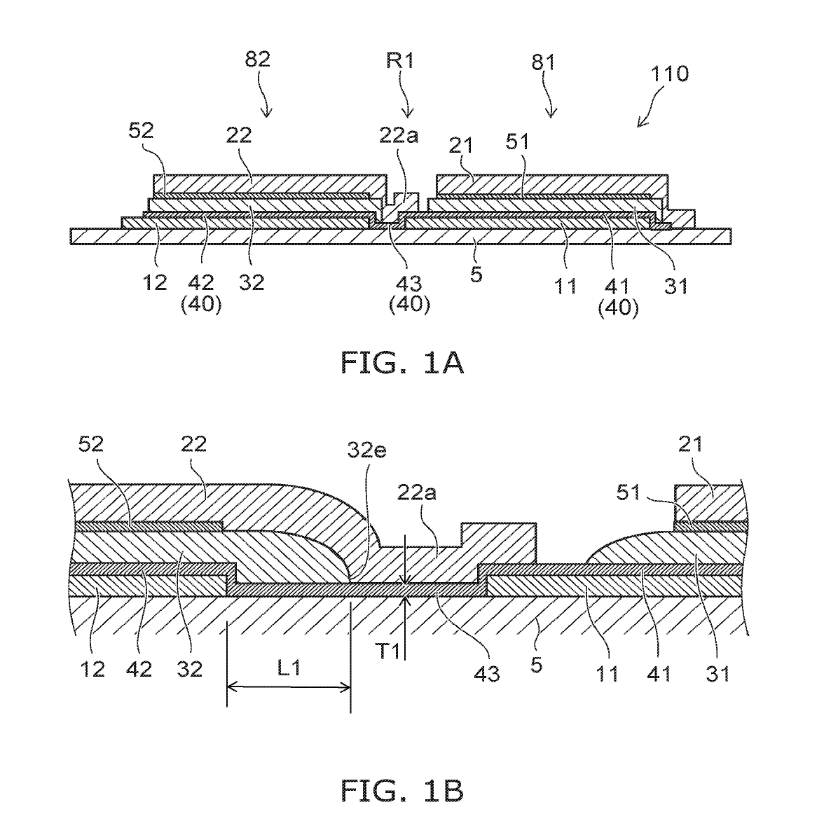

FIG. 1A and FIG. 1B are schematic cross-sectional views showing a solar cell module according to an embodiment.

As shown in FIG. 1A, the solar cell module 110 according to the embodiment includes a substrate 5, a first lower electrode 11, a first upper electrode 21, a first photoelectric conversion layer 31, a first lower intermediate layer 41, a second lower electrode 12, a second upper electrode 22, a second photoelectric conversion layer 32, a second lower intermediate layer 42, and a third lower intermediate layer 43. In the example, the solar cell module 110 further includes a first upper intermediate layer 51 and a second upper intermediate layer 52.

FIG. 1B shows an enlarged region between the first photoelectric conversion layer 31 and the second photoelectric conversion layer 32 of FIG. 1A.

The first upper electrode 21 is provided on the substrate 5. The first lower electrode 11 is provided between the first upper electrode 21 and the substrate 5. The first photoelectric conversion layer 31 is provided between the first upper electrode 21 and the first lower electrode 11. The first lower intermediate layer 41 is provided between the first lower electrode 11 and the first photoelectric conversion layer 31. The first upper intermediate layer 51 is provided between the first upper electrode 21 and the first photoelectric conversion layer 31.

In the following description, a first direction from the first lower electrode 11 toward the first upper electrode 21 is taken as a Z-axis direction. For example, the Z-axis direction is perpendicular to a major surface of the substrate 5. One direction perpendicular to the Z-axis direction is taken as an X-axis direction. A direction perpendicular to the X-axis direction and the Z-axis direction is taken as a Y-axis direction.

The second upper electrode 22 is separated from the first upper electrode 21 in a direction (e.g., the X-axis direction) intersecting the Z-axis direction. The second lower electrode 12 is provided between the second upper electrode 22 and the substrate 5. The second photoelectric conversion layer 32 is provided between the second lower electrode 12 and the second upper electrode 22. The second lower intermediate layer 42 is provided between the second lower electrode 12 and the second photoelectric conversion layer 32. The second upper intermediate layer 52 is provided between the second photoelectric conversion layer 32 and the second upper electrode 22.

The second upper electrode 22 includes a first portion 22a that is provided between the first photoelectric conversion layer 31 and the second photoelectric conversion layer 32 in a direction (e.g., the X-axis direction) intersecting the Z-axis direction.

The third lower intermediate layer 43 is provided between the first portion 22a and the substrate 5 and between the first portion 22a and the first lower electrode 11.

The third lower intermediate layer 43 is continuous with the first lower intermediate layer 41 and the second lower intermediate layer 42. For example, each of the first to third lower intermediate layers 41 to 43 may be one portion included in one film (for example, a lower intermediate layer 40). In other words, the lower intermediate layer 40 includes a first lower region (the first lower intermediate layer 41), a second lower region (the second lower intermediate layer 42), and a third lower region (the third lower intermediate layer 43). For example, the third lower intermediate layer 43 includes the same material as the first lower intermediate layer 41 and includes the same material as the second lower intermediate layer 42.

For example, a first solar cell 81 is formed of the first lower electrode 11, the first upper electrode 21, the first photoelectric conversion layer 31, the first lower intermediate layer 41, and the first upper intermediate layer 51.

Similarly, a second solar cell 82 is formed of the second lower electrode 12, the second upper electrode 22, the second photoelectric conversion layer 32, the second lower intermediate layer 42, and the second upper intermediate layer 52.

The second upper electrode 22 is electrically connected to the first lower electrode 11. The first solar cell 81 and the second solar cell 82 are, for example, solar cells that are connected in series with each other.

A not-shown sealing film is provided on the first solar cell 81 and the second solar cell 82.

The solar cells are photoelectric conversion devices that generate, between the upper electrode and the lower electrode, a voltage corresponding to the light amount of the incident light. The photoelectric conversion layers of the embodiment include organic semiconductors. The solar cell module 110 is, for example, an organic thin film solar cell module.

In the example, the substrate 5, the first lower electrode 11, and the second lower electrode 12 are light-transmissive. The substrate 5 is, for example, a transparent substrate. The first lower electrode 11 and the second lower electrode 12 are, for example, transparent electrodes. Here, the light transmissivity is, for example, the property of transmitting with a transmittance of 70% or more for light of wavelengths that can generate excitons by being absorbed by the first photoelectric conversion layer 31 or the second photoelectric conversion layer 32.

For example, the light that is incident on the substrate 5 passes through the first lower electrode 11 and is incident on the first photoelectric conversion layer 31. Thereby, excitons are generated in the first photoelectric conversion layer 31. The excitons are separated into electrons and holes.

The first lower intermediate layer 41 is, for example, a first charge transport layer. In the example, the first lower intermediate layer 41 is an electron transport layer. For example, the electron transport layer efficiently transports electrons and blocks holes. The first lower electrode 11 is a negative electrode. The electrons that are generated inside the first photoelectric conversion layer 31 are extracted to the outside from the first lower electrode 11 via the first lower intermediate layer 41.

The first upper intermediate layer 51 is, for example, a second charge transport layer. In the example, the first upper intermediate layer 51 is a hole transport layer. For example, the hole transport layer efficiently transports holes and blocks electrons. The first upper electrode 21 is a positive electrode. The holes that are generated inside the first photoelectric conversion layer 31 are extracted to the outside from the first upper electrode 21 via the first upper intermediate layer 51.

Similarly, in the example, the second lower intermediate layer 42 is an electron transport layer; the second lower electrode 12 is a negative electrode; the second upper intermediate layer 52 is a hole transport layer; and the second upper electrode 22 is a positive electrode. Thereby, in the second solar cell 82 as well, the electrons and the holes are extracted from the second photoelectric conversion layer 32 similarly to the first solar cell 81.

The light may be caused to be incident on the first photoelectric conversion layer 31 and the second photoelectric conversion layer 32 from the first upper electrode 21 side and the second upper electrode 22 side. In such a case, the first upper electrode 21 and the second upper electrode 22 are transparent electrodes.

In the embodiment, the first lower intermediate layer 41 and the second lower intermediate layer 42 may be hole transport layers; and the first upper intermediate layer 51 and the second upper intermediate layer 52 may be electron transport layers. The first lower electrode 11 and the second lower electrode 12 may be positive electrodes; and the first upper electrode 21 and the second upper electrode 22 may be negative electrodes.

The light that contributes to the power generation of the solar cell module 110 is not limited to sunlight. For example, the solar cell module 110 generates power using even the light emitted from a light source such as an electric bulb, etc.

Members included in the solar cell module according to the embodiment will now be described.

### Substrate

The substrate 5 supports the other components. The substrate 5 includes, for example, a material that is not altered by the heat and organic solvents of the formation of the lower electrodes, etc. For example, an inorganic material such as alkali-free glass, quartz glass, or the like is used as the material of the substrate 5. The material of the substrate 5 may be, for example, a polymer film or a plastic such as polyethylene, polyethylene terephthalate (PET), polyethylene naphthalate (PEN), polyimide, polyamide, polyamide-imide, a liquid crystal polymer, a cycloolefin polymer, etc. The substrate 5 may include a metal substrate such as stainless steel (SUS), silicon, etc. The substrate 5 includes a material that is light-transmissive. In the case where the light is incident from the first upper electrode 21, a material that is not light-transmissive may be included in the substrate 5. The thickness of the substrate 5 is not particularly limited as long as the substrate 5 has enough strength to support the other components.

### Upper Intermediate Layer

The first upper intermediate layer 51 (the hole transport layer) is disposed between the first upper electrode 21 (the positive electrode) and the first photoelectric conversion layer 31 (the photoactive layer). The first upper intermediate layer 51 efficiently transports holes. The first upper intermediate layer 51 suppresses the annihilation of the excitons generated at the interface vicinity of the first photoelectric conversion layer 31.

The first upper intermediate layer 51 includes, for example, an organic conductive polymer such as a polythiophene polymer, polyaniline, polypyrrole, etc. For example, PEDOT/PSS (poly(3,4-ethylenedioxythiophene)-poly(styrene sulfonate)) or the like is used as the polythiophene polymer. For example, Clevios PH 500, Clevios PH, Clevios PV AI 4083, and Clevios HIL 1.1 of H. C. Starck are typical products for the polythiophene polymer. Molybdenum oxide is a favorable material as the inorganic substance.

In the case where Clevios PH 500 is used as the material of the first upper intermediate layer 51, it is favorable for the thickness of the first upper intermediate layer 51 to be not less than 10 nm and not more than 100 nm. In the case where the first upper intermediate layer 51 is too thin, the effect of blocking the electrons decreases. In the case where the first upper intermediate layer 51 is too thick, the film resistance becomes large; and the light conversion efficiency decreases because the current generated by the first photoelectric conversion layer 31 is undesirably limited.

The method for forming the first upper intermediate layer 51 is not particularly limited as long as the method can form a thin film. For example, the first upper intermediate layer 51 may be formed by coating using spin coating, etc. After coating the material of the first upper intermediate layer 51 to have the desired thickness, heating and drying are performed using a hotplate, etc. For example, it is favorable for the heating and the drying to be performed at 140 to 200° C. for not less than about 1 minute and not more than about 10 minutes. It is desirable for the solution that is coated to be pre-filtered using a filter. The description of the first upper intermediate layer 51 recited above is similar for the second upper intermediate layer 52 as well.

### Lower Intermediate Layer

The first lower intermediate layer 41 (the electron transport layer) is disposed between the first lower electrode 11 (the negative electrode) and the first photoelectric conversion layer 31 (the photoactive layer). For example, the first lower intermediate layer 41 levels (smoothes) the unevenness of the first lower electrode 11 and prevents shorts of the solar cell. The first lower intermediate layer 41 blocks holes and efficiently transports electrons. The first lower intermediate layer 41 suppresses the annihilation of the excitons generated at the interface vicinity between the first photoelectric conversion layer 31 and the first lower intermediate layer 41.

The material of the first lower intermediate layer 41 includes a metal oxide. For example, amorphous titanium oxide obtained by hydrolysis of titanium alkoxide by a sol-gel method, etc., may be used as the metal oxide. The method for forming the first lower intermediate layer 41 is not particularly limited as long as the method can form a thin film. For example, spin coating is used to form the first lower intermediate layer 41. In the case where titanium oxide is used as the material of the first lower intermediate layer 41, it is desirable for the thickness of the first lower intermediate layer 41 to be not less than 5 nm and not more than 50 nm. In the case where the thickness of the first lower intermediate layer 41 is thinner than the range recited above, the hole blocking effect decreases. Therefore, the excitons that are generated by the first photoelectric conversion layer 31 undesirably deactivate before dissociating into electrons and holes; and the current cannot be extracted efficiently. In the case where the first lower intermediate layer 41 is too thick, the film resistance becomes large; and the light conversion efficiency decreases because the current generated by the first photoelectric conversion layer 31 is undesirably limited. It is favorable for the solution that is coated to be pre-filtered using a filter. After coating the solution to have the desired thickness, heating and drying are performed using a hotplate, etc. The heating and the drying are performed at a temperature of not less than 50° C. and not more than 100° C. for not less than about 1 minute and not more than about 10 minutes. The heating and the drying are performed while promoting hydrolysis in air. Metal calcium and the like are favorable materials in the case where an inorganic substance is used. The description of the first lower intermediate layer 41 recited above is similar for the second lower intermediate layer 42 as well. A material and a formation method similar to those of the first lower intermediate layer 41 may be used for the third lower intermediate layer 43.

### Upper Electrode and Lower Electrode

In the description of the first lower electrode 11, the first upper electrode 21, the second lower electrode 12, and the second upper electrode 22 hereinbelow, simply “electrode” refers to at least one of the first lower electrode 11, the first upper electrode 21, the second lower electrode 12, or the second upper electrode 22.

The material of the electrode is not particularly limited as long as the material is conductive. Vacuum vapor deposition, sputtering, ion plating, plating, coating, or the like is used to form the electrode. Thereby, a film that includes a conductive material may be formed as the electrode. A conductive metal thin film, a conductive metal oxide film, etc., may be used as the material of the electrode.

The electrode that is light-transmissive includes a conductive material that is transparent or semi-transparent. A conductive metal oxide film, a semi-transparent metal thin film, etc., may be used as the transparent or semi-transparent conductive material. Specifically, a film that is made using conductive glass made of indium oxide, zinc oxide, tin oxide, a complex of these substances such as indium-tin-oxide (ITO), fluorine-doped tin oxide (FTO), indium-zinc-oxide, etc., may be used as the metal oxide film. The material of the metal thin film includes gold, platinum, silver, copper, etc. It is favorable for the material of the light-transmissive electrode to be ITO or FTO. The material of the light-transmissive electrode may include an organic conductive polymer such as polyaniline, a derivative of polyaniline, polythiophene, a derivative of polythiophene, etc.

In the case where ITO is used as the material of the electrode, it is favorable for the thickness of the electrode to be not less than 30 nanometers (nm) and not more than 300 nm. In the case where the electrode is thinner than 30 nm, the conductivity decreases; the resistance becomes high; and this may cause the photoelectric conversion efficiency to decrease. In the case where the electrode is thicker than 300 nm, the flexibility of the ITO decreases; and there are cases where the ITO breaks when stress is applied. It is favorable for the sheet resistance of the electrode to be low, e.g., 10Ω/□ or less.

For example, the electrode that is used as the positive electrode is formed using a material having a high work function. In such a case, for example, it is favorable for the electrode used as the negative electrode to include a material having a low work function. For example, an alkaline metal, an alkaline earth metal, etc., may be used as the material having the low work function. Specifically Li, In, Al, Ca, Mg, Sm, Tb, Yb, Zr, Na, K, Rb, Cs, Ba, or an alloy of these elements may be used. An alloy of at least one of these materials having low work functions and gold, silver, platinum, copper, manganese, titanium, cobalt, nickel, tungsten, tin, or the like may be used. Examples of the alloy include a lithium-aluminum alloy, a lithium-magnesium alloy, a lithium-indium alloy, a magnesium-silver alloy, a magnesium-indium alloy, a magnesium-aluminum alloy, an indium-silver alloy, a calcium-aluminum alloy, etc.

The electrode may be a single layer or may have a structure in which layers including materials having different work functions are stacked.

The thickness of the upper electrode (the upper electrode 21 or the second upper electrode 22) is, for example, not less than 10 nm and not more than 300 nm. In the case where the upper electrode is thinner than the range recited above, the resistance becomes too large; and the charge that is generated cannot be conducted sufficiently to the external circuit. In the case where the upper electrode is thicker than the range recited above, a long period of time is necessary to form the electrode; therefore, the material temperature increases; and the photoelectric conversion layer (the organic layer) may be damaged and the performance may undesirably degrade. Because a large amount of material is used, the time occupied by the manufacturing apparatus lengthens which may increase the cost.

### Photoelectric Conversion Layer

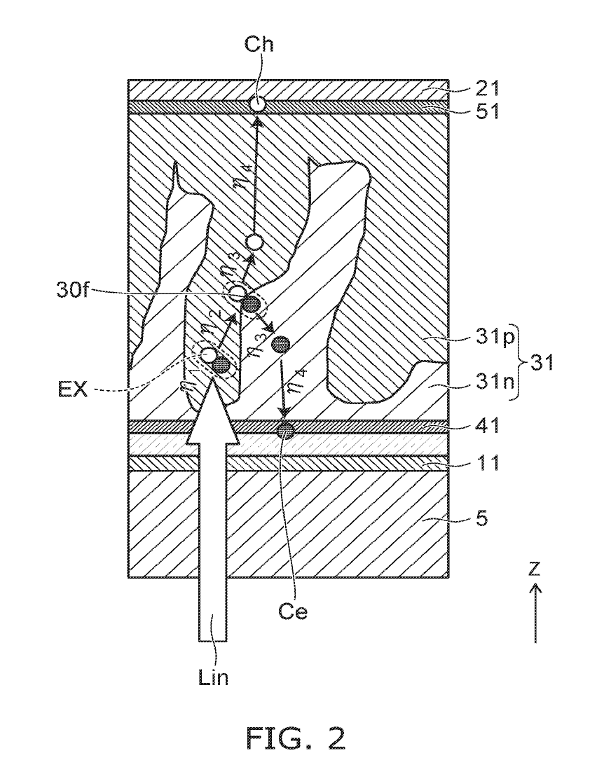

FIG. 2 is a schematic cross-sectional view showing a portion of the solar cell module according to the embodiment.

FIG. 2 shows a portion of the first solar cell 81.

As shown in FIG. 2, the first photoelectric conversion layer 31 (the photoactive layer) is disposed between the first upper electrode 21 (the positive electrode) and the first lower electrode 11 (the negative electrode). The first photoelectric conversion layer 31 includes a semiconductor layer 31n of a first conductivity type and a semiconductor layer 31p of a second conductivity type. For example, the semiconductor layer 31n is provided between the first lower intermediate layer 41 and the semiconductor layer 31p. For example, the first conductivity type is an n-type; and the second conductivity type is a p-type. The first conductivity type may be the p-type; and the second conductivity type may be the n-type.

The first photoelectric conversion layer 31 is, for example, a thin film that has a structure in which the semiconductor layer 31n and the semiconductor layer 31p have a bulk heterojunction. A characteristic of the bulk heterojunction photoelectric conversion layer is that the n-type semiconductor and the second p-type semiconductor are blended and a nano-order p-n junction spreads through the entire photoelectric conversion layer. For example, the structure is called a microlayer-separated structure.

In the bulk heterojunction first photoelectric conversion layer 31, the current is obtained by utilizing the photocharge separation occurring at the junction surface between the p-type semiconductor and the n-type semiconductor which are mixed. The region that actually contributes to the power generation spreads through the entire first photoelectric conversion layer 31; and the p-n junction region is wider for the bulk heterojunction first photoelectric conversion layer 31 than for a conventional stacked organic thin film solar cell. Accordingly, compared to the stacked organic thin film solar cell, the region that contributes to the power generation is thicker for the bulk heterojunction organic thin film solar cell. Thereby, the absorption efficiency of the photons also increases; and the current that is extracted also increases.

The p-type semiconductor includes a material having electron-donating properties. On the other hand, the n-type semiconductor includes a material having electron-accepting properties. In the embodiment, at least one of the p-type semiconductor or the n-type semiconductor includes an organic semiconductor.

For example, the first photoelectric conversion layer 31 generates excitons EX by the semiconductor layer 31n or the semiconductor layer 31p absorbing light Lin. The excitons EX that are generated move by diffusion toward a p-n junction surface 30f (the junction surface between the semiconductor layer 31n and the semiconductor layer 31p). The excitons EX that reach the p-n junction surface 30f are separated into electrons Ce and holes Ch. The holes Ch are transported to the first upper electrode 21. The electrons Ce are transported to the first lower electrode 11. Thereby, the electrons Ce and the holes Ch (the photo carriers) are extracted to the outside.

As the p-type organic semiconductor, for example, polythiophene, a derivative of polythiophene, polypyrrole, a derivative of polypyrrole, a pyrazoline derivative, an arylamine derivative, a stilbene derivative, a triphenyldiamine derivative, oligothiophene, a derivative of oligothiophene, polyvinyl carbazole, a derivative of polyvinyl carbazole, polysilane, a derivative of polysilane, a polysiloxane derivative having aromatic amine at a side chain or a main chain, polyaniline, a derivative of polyaniline, a phthalocyanine derivative, porphyrin, a derivative of porphyrin, polyphenylene vinylene, a derivative of polyphenylene vinylene, polythienylene vinylene, a derivative of polythienylene vinylene, etc., may be used. These may be used in combination. Also, a copolymer of these substances may be used. For example, a thiophene-fluorene copolymer, a phenylene ethynylene-phenylene vinylene copolymer, etc., may be used as the copolymer.

It is favorable to use polythiophene, which is a pi-conjugated conductive polymer, or a derivative of polythiophene as the p-type organic semiconductor. For polythiophene and derivatives of polythiophene, excellent stereoregularity can be ensured; and the solubility in solvents is relatively high. The polythiophene and the derivatives of polythiophene are not particularly limited as long as a compound having a thiophene skeleton is used. Specific examples of polythiophene and derivatives of polythiophene are, for example, polyalkylthiophene, polyarylthiophene, polyalkyl isothionaphthene, polyethylene dioxythiophene, etc. Poly(3-methylthiophene), poly(3-butylthiophene), poly(3-hexylthiophene), poly(3-octylthiophene), poly(3-decylthiophene), poly(3-dodecylthiophene), etc., may be used as the polyalkylthiophene. Poly(3-phenylthiophene), poly(3-(p-alkylphenylthiophene)), etc., may be used as the polyarylthiophene. Poly(3-butyl isothionaphthene), poly(3-hexyl isothionaphthene), poly(3-octyl isothionaphthene), poly(3-decyl isothionaphthene), etc., may be used as the polyalkyl isothionaphthene.

In recent years, derivatives of PCDTBT (poly[N-9″-hepta-decanyl-2,7-carbazole-alt-5,5-(4′,7′-di-2-thienyl-2′,1′,3′-benzothiadiazole)]) or the like which are copolymers made of carbazole, benzothiadiazole, and thiophene are known as compounds for which excellent photoelectric conversion efficiency is obtained.

Films of these conductive polymers can be formed by coating solutions of these conductive polymers dissolved in solvents. Accordingly, an organic thin film solar cell that has a large surface area can be manufactured inexpensively using inexpensive equipment by printing, etc.

It is favorable to use fullerene or a derivative of fullerene as the n-type organic semiconductor. The fullerene derivative that is used here is not particularly limited as long as the fullerene derivative is a derivative having a fullerene skeleton. Specifically, a derivative configured to have a basic skeleton of C₆₀, C₇₀, C₇₆, C₇₈, C₈₄, etc., may be used. The carbon atoms of the fullerene skeleton of the fullerene derivative may be modified with any functional group. A ring may be formed of functional groups bonded to each other. Fullerene derivatives also include fullerene-binding polymers. It is favorable for the fullerene derivative to include a functional group having high affinity with the solvent and to have high solubility in the solvent.

For example, a hydrogen atom, a hydroxide group, a halogen atom, an alkyl group, an alkenyl group, a cyano group, an alkoxy group, an aromatic heterocyclic group, etc., may be used as the functional group of the fullerene derivative. For example, a fluorine atom, a chlorine atom, etc., may be used as the halogen atom. For example, a methyl group, an ethyl group, etc., may be used as the alkyl group. For example, a vinyl group, etc., may be used as the alkenyl group. For example, a methoxy group, an ethoxy group, etc., may be used as the alkoxy group. For example, an aromatic hydrocarbon group, a thienyl group, a pyridyl group, etc., may be used as the aromatic heterocyclic group. Also, for example, a phenyl group, a naphthyl group, etc., may be used as the aromatic hydrocarbon group. More specifically, hydrogenated fullerene, oxide fullerene, a fullerene metal complex, etc., may be used. For example, C₆₀H₃₆, C₇₀H₃₆, etc., may be used as the hydrogenated fullerene. For example, C₆₀, C₇₀, etc., may be used as the oxide fullerene. Among those described above, it is particularly favorable to use 60PCBM ([6,6]-phenyl C₆₁ butyric acid methyl ester) or 70PCBM ([6,6]-phenyl C₇₁ butyric acid methyl ester) as the fullerene derivative. In the case where unmodified fullerene is used, it is favorable to use C₇₀. The generation efficiency of the photo carriers of fullerene C₇₀ is high; and fullerene C₇₀ is suited to use in the organic thin film solar cell.

In the case where the p-type semiconductor is the P3AT-type, it is favorable for the mixing ratio of the n-type organic semiconductor and the p-type organic semiconductor in the first photoelectric conversion layer 31 to be about n:p=1:1. In the case where the p-type semiconductor is the PCDTBT-type, it is favorable for the mixing ratio to be about n:p=4:1.

The organic semiconductor can be coated by dissolving the organic semiconductor in a solvent. An unsaturated hydrocarbon solvent, a halogenated aromatic hydrocarbon solvent, a halgenated saturated hydrocarbon solvent, an ether, etc., may be used as the solvent that is used in the coating. Toluene, xylene, tetralin, decalin, mesitylene, n-butylbenzene, sec-butylbenzene, tert-butylbenzene, etc., may be used as the unsaturated hydrocarbon solvent. Chlorobenzene, dichlorobenzene, trichlorobenzene, etc., may be used as the halogenated aromatic hydrocarbon solvent. Carbon tetrachloride, chloroform, dichloromethane, dichloroethane, chlorobutane, bromobutane, chloropentane, chlorohexane, bromohexane, chlorocyclohexane, etc., may be used as the halgenated saturated hydrocarbon solvent. Tetrahydrofuran, tetrahydropyran, etc., may be used as the ether. A halogen aromatic solvent is particularly favorable. These solvents may be used independently or mixed.

Spin coating, dip coating, casting, bar coating, roll coating, wire-bar coating, spraying, screen printing, gravure printing, flexographic printing, offset printing, gravure-offset printing, dispenser coating, nozzle coating, capillary coating, inkjet, etc., may be used as the method for forming the film by coating the solution. These coating methods may be used independently or in combination. The description of the first photoelectric conversion layer 31 recited above is similar for the second photoelectric conversion layer 32 as well.

The resistance value of the transparent electrode included in the organic thin film solar cell module is high compared to that of a metal. Therefore, for example, multiple solar cells are provided and connected in series. Thereby, for example, the increase of the resistance value of the transparent electrode as the surface area of the transparent electrode increases can be suppressed. For example, the size of one solar cell is about 10 to 15 mm; and about ten to forty solar cells are connected in series on a substrate having a size of about 10 cm to 15 cm.

A connection region R1 is provided between the multiple solar cells arranged on the substrate. The transparent electrode of the solar cell is electrically connected to the counter electrode (the upper electrode) of an adjacent solar cell in the connection region R1. For example, a portion of the first lower electrode 11 is electrically connected to a portion of the second upper electrode 22 in the connection region R1. Thus, the multiple solar cells can be connected in series.

As described above, the photoelectric conversion layer, the lower intermediate layer, the upper intermediate layer, etc., can be formed by coating in the organic thin film solar cell. When forming the layers by coating, the layers are divided to correspond to each of the solar cells. For example, the lower intermediate layer of one solar cell and the lower intermediate layer of an adjacent solar cell are provided to be separated with the connection region R1 interposed. Thereby, the multiple solar cells are formed to be separated from each other and can be connected in series.

However, in the case where the layers are thus divided in the connection region R1, a difference undesirably occurs between the appearance of the connection region R1 and the appearance of the region where the solar cell is provided when a user views the solar cell module. For example, the connection region R1 may be highly noticeable; and the appearance of the solar cell module may degrade.

Conversely, in the solar cell module according to the embodiment, the third lower intermediate layer 43 is provided in the connection region R1. The third lower intermediate layer 43 is continuous with the first lower intermediate layer 41 and the second lower intermediate layer 42. Therefore, the difference between the appearance of the solar cell and the appearance of the connection region R1 can be reduced. Thereby, for example, the connection region R1 is not highly noticeable; and the appearance of the solar cell module can be improved.

In the embodiment, it is desirable for the resistance value (the resistance value along the X-axis direction) of the third lower intermediate layer 43 to be sufficiently higher than the resistance value of the first portion 22a. It is desirable for the sheet resistance of the third lower intermediate layer 43 to be sufficiently higher than the sheet resistance of the first portion 22a. Thereby, the occurrence of shorts between the first lower electrode 11 and the second lower electrode 12 can be suppressed even in the case where the third lower intermediate layer 43 includes the same material as the first lower intermediate layer 41 and the second lower intermediate layer 42. Thereby, the first solar cell 81 and the second solar cell 82 can be connected substantially in series.

On the other hand, in the case where the third lower intermediate layer 43 includes the same material as the first lower intermediate layer 41, it is desirable for the resistivity of the third lower intermediate layer 43 not to be too high so that the first lower intermediate layer 41 can function as the charge transport layer.

For example, the resistance value of the third lower intermediate layer 43 is not less than 1×10⁶ times and not more than 1×10¹¹ times the resistance value of the first portion 22a. For example, the sheet resistance value of the third lower intermediate layer 43 is not less than 1×10⁵Ω/□ and not more than 1×10¹⁰Ω/□. For example, the resistivity of the third lower intermediate layer 43 is not less than 1×10⁵ times and not more than 1×10¹⁰ times the resistivity of the first portion 22a. For example, the resistivity can be determined by analyzing the material by SIMS, etc.

As shown in FIG. 1B, the second photoelectric conversion layer 32 includes an end portion 32e that is positioned between the first lower electrode 11 and the second lower electrode 12. The end portion 32e is the end portion in a direction (e.g., the X-axis direction) intersecting the first direction (the Z-axis direction). It is desirable for a distance L1 (the distance along the X-axis direction) between the end portion 32e and the second lower electrode 12 to be longer than a thickness T1 (the length of the film along the Z-axis direction) of the third lower intermediate layer 43. For example, the distance L1 is not less than 1000 times and not more than 50000 times the thickness T1. Thereby, the resistance value of the third lower intermediate layer 43 can be set to be high. For example, the thickness T1 is not less than 5 nm and not more than 50 nm; and the distance L1 is not less than 50 μm and not more than 250 μm. For example, the thickness T1 and the distance L1 can be determined by observing the cross section of the solar cell module 110 using an electron microscope, etc.

By providing a third lower intermediate layer 43 such as that described above, the first solar cell 81 and the second solar cell 82 can be connected substantially in series; and the appearance of the solar cell module can be improved.

An example of a method for manufacturing the solar cell module 110 according to the embodiment will now be described.

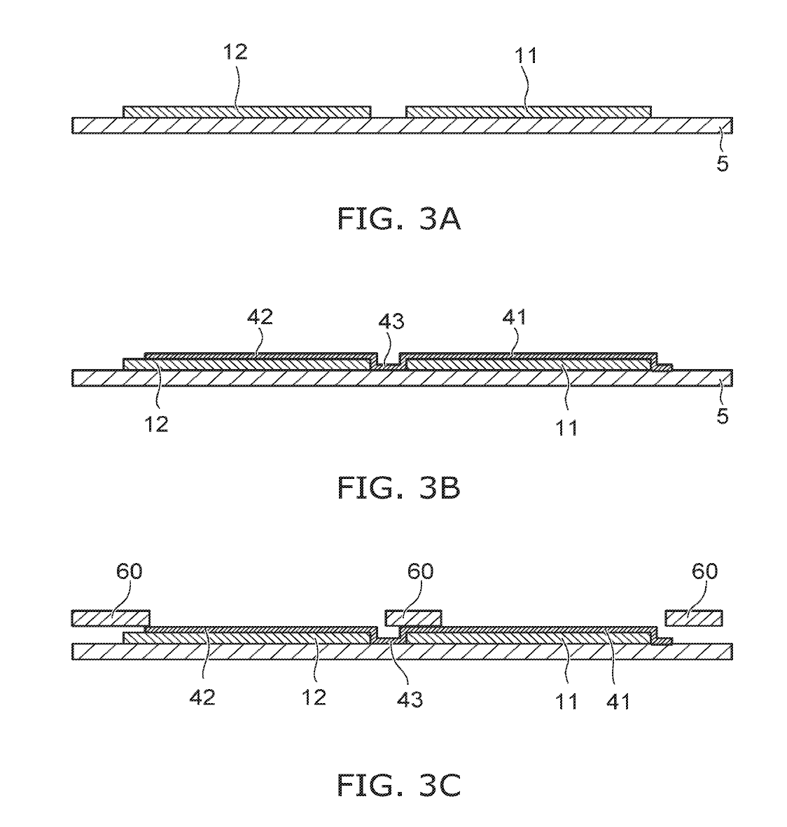

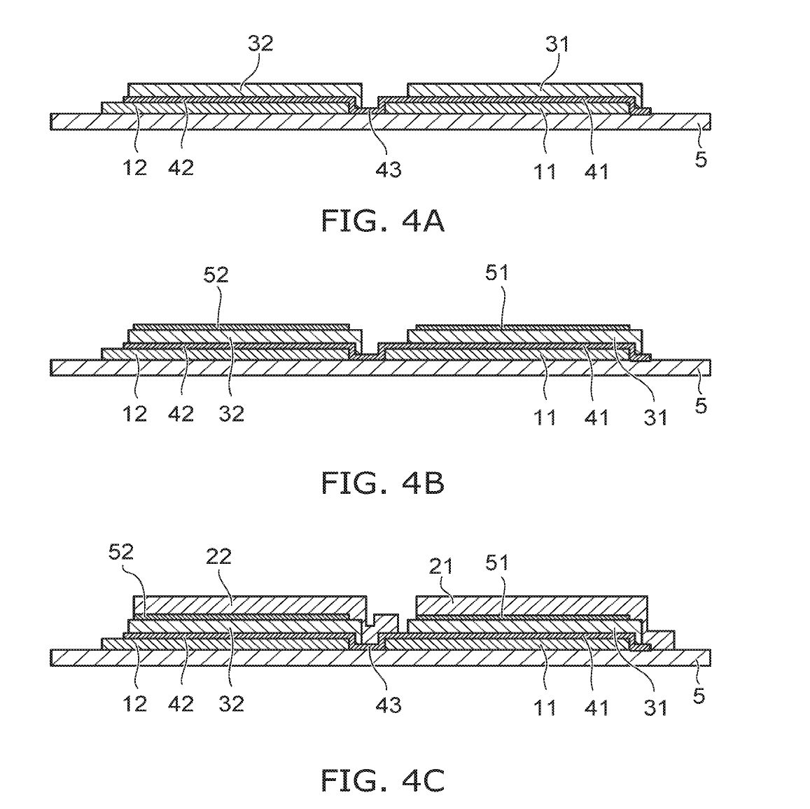

FIG. 3A, FIG. 3B, FIG. 3C, FIG. 4A, FIG. 4B, and FIG. 4C are schematic cross-sectional views showing the method for manufacturing the solar cell module according to the embodiment.

As shown in FIG. 3A, the first lower electrode 11 and the second lower electrode 12 are formed on the substrate 5 (a lower electrode formation process). For example, the substrate 5 includes glass as a transparent substrate. An ITO film that is used to form the first lower electrode 11 and the second lower electrode 12 is formed on the substrate 5 by sputtering. Subsequently, the first lower electrode 11 and the second lower electrode 12 are formed by patterning the ITO film by etching.

Subsequently, as shown in FIG. 3B, the lower intermediate layer 40 (the first lower intermediate layer 41, the second lower intermediate layer 42, and the third lower intermediate layer 43) is formed (a lower intermediate layer formation process). As described below, a photoelectric conversion layer is formed by coating on the first to third lower intermediate layers 41 to 43. Here, the first to third lower intermediate layers 41 to 43 include a material that is repellent to the liquid (the photoactive layer ink) including the organic semiconductor used to coat the photoelectric conversion layer.

In the example, a Cs₂CO₃ film is used as the first to third lower intermediate layers 41 to 43. For example, the Cs₂CO₃ film is coated to be continuous over the multiple cells (the multiple lower electrodes). In the case where the Cs₂CO₃ film is used, a solution in which Cs₂CO₃ is dissolved in a solvent is coated to be continuous over the multiple cells using bar coating. Of the Cs₂CO₃ film thus formed, the portion that is formed on the first lower electrode 11 becomes the first lower intermediate layer 41; the portion that is formed on the second lower electrode 12 becomes the second lower intermediate layer 42; and the portion that is formed on the substrate 5 between the first lower electrode 11 and the second lower electrode 12 becomes the third lower intermediate layer 43.

Subsequently, the surface state of the first lower intermediate layer 41 and the surface state of the second lower intermediate layer 42 are modified (a surface treatment process). For example, as shown in FIG. 3C, a light-shielding unit 60 (a mask) is formed in the region corresponding to the end portion of the solar cell. For example, the light-shielding unit 60 is formed on the third lower intermediate layer 43. Then, UV ozone treatment is performed on the light-shielding unit 60. Thereby, the first lower intermediate layer 41 and the second lower intermediate layer 42 that correspond to the openings of the mask undergo UV ozone treatment. The third lower intermediate layer 43 that is provided under the light-shielding unit 60 does not undergo UV ozone treatment. The UV ozone treatment modifies the wettability of the surface of the first lower intermediate layer 41 for the photoactive layer ink and the wettability of the surface of the second lower intermediate layer 42 for the photoactive layer ink. The surface of the first lower intermediate layer 41 and the surface of the second lower intermediate layer 42 have affinity for the liquid including the organic semiconductor. The characteristic of the third lower intermediate layer 43 of repelling the liquid including the organic semiconductor is maintained. Subsequently, the light-shielding unit 60 is removed.

As shown in FIG. 4A, the first photoelectric conversion layer 31 and the second photoelectric conversion layer 32 are formed (a photoelectric conversion layer formation process). The first photoelectric conversion layer 31 and the second photoelectric conversion layer 32 are formed by coating a liquid including an organic semiconductor. The liquid that includes the organic semiconductor is coated to be continuous over the multiple cells. Here, as described in reference to FIG. 3C, the liquid that includes the organic semiconductor is repelled in the region where the UV ozone treatment is not performed. Accordingly, the photoelectric conversion layer is divided every cell. In other words, the first photoelectric conversion layer 31 is formed on the first lower intermediate layer 41; and the second photoelectric conversion layer 32 is formed on the second lower intermediate layer 42. The photoelectric conversion layer is not formed on the third lower intermediate layer 43. Thus, by the third lower intermediate layer 43 including the material having the characteristic of repelling the liquid including the organic semiconductor, the coating area of the liquid including the organic semiconductor can be limited.

Subsequently, as shown in FIG. 4B, the first upper intermediate layer 51 is formed on the first photoelectric conversion layer 31; and the second upper intermediate layer 52 is formed on the second photoelectric conversion layer 32 (an upper intermediate layer formation process). The first upper intermediate layer 51 and the second upper intermediate layer 52 include, for example, a V₂O₅ film.

Then, by coating, vapor deposition, or the like as shown in FIG. 4C, the first upper electrode 21 is formed on the first upper intermediate layer 51; and the second upper electrode 22 is formed on the second upper intermediate layer 52 (an upper electrode formation process). The first upper electrode 21 and the second upper electrode 22 include, for example, a Ag film.

As described above, the solar cell module 110 according to the embodiment is completed.

Other than bar coating, the lower intermediate layer and the photoelectric conversion layer may be coated by die coating, wire-bar coating, spraying, screen printing, dispenser coating, nozzle coating, or capillary coating. In these methods as well, the lower intermediate layer and the photoelectric conversion layer can be coated to be continuous over the multiple cells.

Compared to a solar cell module having an inorganic material such as silicon, GIGS, CdTe, etc., as a base, the organic thin film solar cell module described above can be produced by a simple method such as coating or printing. Therefore, the manufacturing cost can be reduced. In the case where an organic polymer material is used, the film is formed by dissolving an organic material in a solvent and by coating the solvent. In this method, compared to the case where vapor deposition or sputtering is used, the initial cost can be suppressed because a vacuum apparatus is not used.

For example, in a method of a reference example, the photoelectric conversion layer and the lower intermediate layer are formed by coating the photoelectric conversion layer and the lower intermediate layer for each solar cell. In this method, if the width of the connection region R1 is too narrow, it is difficult to separately coat the photoelectric conversion layer for each cell; and this may cause the yield to decrease.

Conversely, in the method for manufacturing the solar cell module 110 according to the embodiment, the third lower intermediate layer 43 that corresponds to the connection region R1 is repellent to the liquid including the organic semiconductor. The liquid that includes the organic semiconductor is coated over the multiple solar cells. Thereby, it is easy to set the width of the connection region R1 to be narrow. Also, for example, the flatness of the solar cell module can be improved. For example, by setting the width of the connection region R1 to be narrow, the connection region R1 is not easily noticeable when the user views the solar cell module 110. Thereby, the appearance of the solar cell module can be improved.

There are cases where the photoelectric conversion efficiency of an organic thin film solar cell module is low compared to that of an inorganic solar cell module.

For example, the photoelectric conversion layer is not provided in the connection region R1 described above. Therefore, the connection region R1 does not contribute to the power generation. Therefore, in the case where the connection region R1 is large, the aperture ratio of the organic thin film solar cell module (the proportion of the surface area of the region contributing to the power generation to the surface area of the solar cell module) decreases.

When the power generation characteristics of the solar cell improve and the generated current increases, the current that flows in the transparent electrodes of the first lower electrode 11 and the second lower electrode 12 also increases. In the case where the potential difference that occurs inside the transparent electrodes is large, the photoelectric characteristics of the solar cell module degrade. Therefore, for example, the potential difference that occurs inside the transparent electrodes can be reduced by setting the width of the solar cell to be narrow. On the other hand, in the case where the width of the solar cell is set to be narrow, the aperture ratio of the solar cell module decreases if the width of the connection region R1 is not set to be narrow accordingly. However, in the case where the photoelectric conversion layer and the like are coated for each cell, setting the connection region R1 to be narrow may cause the yield to decrease.

Conversely, according to the method for manufacturing the solar cell module 110 according to the embodiment, the narrow connection region R1 can be formed by setting the surface of the third lower intermediate layer 43 to be repellent to the liquid including the organic semiconductor.

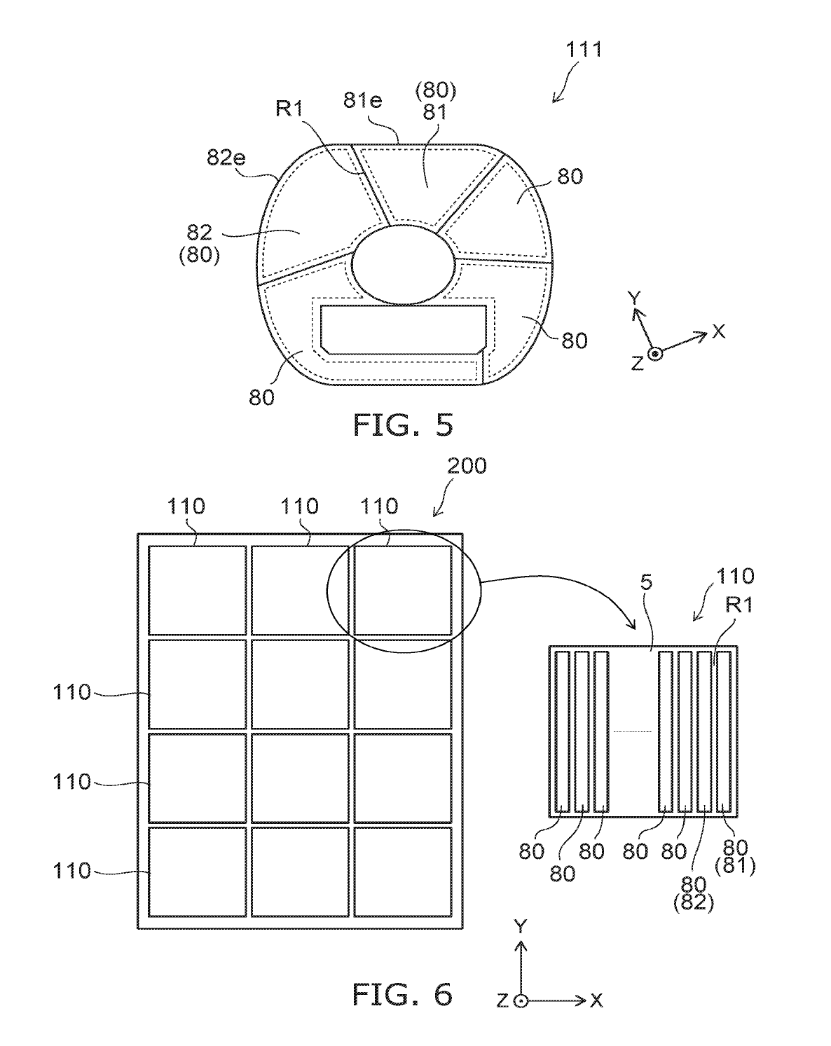

FIG. 5 is a schematic plan view showing another solar cell module according to the embodiment.

As shown in FIG. 5, the solar cell module 111 according to the embodiment includes multiple solar cells 80 provided on the substrate. The multiple solar cells 80 include, for example, the first solar cell 81 and the second solar cell 82. A description similar to that of the first solar cell 81 or the second solar cell 82 is applicable to each of the multiple solar cells 80. The solar cell module 111 is, for example, a solar cell module used in a wristwatch.

The planar configurations (the configurations projected onto the X-Y plane) of the multiple solar cells 80 are different from each other. For example, the planar configuration of the first solar cell 81 is different from the planar configuration of the second solar cell 82. The surface area of the first solar cell 81 may be different from the surface area of the second solar cell 82.

For example, when projected onto the X-Y plane, the first solar cell 81 includes an end portion 81e that extends in a direction that is different from the direction (the Y-axis direction) in which the connection region R1 extends. When projected onto the X-Y plane, the second solar cell 82 includes an end portion 82e that extends in a direction that is different from the direction in which the connection region R1 extends and the direction in which the end portion 81e extends. The end portion 81e and the end portion 82e may have curved configurations.

In the solar cell module that is included in the wristwatch as well, by providing the third lower intermediate layer 43, the difference between the appearance of the solar cell and the appearance of the connection region R1 can be reduced. The appearance of the solar cell module can be improved. Thereby, the decorative quality of the wristwatch can be improved.

Because the surface area of the location where the solar cell module for the wristwatch is mounted is limited, the module surface area is relatively small. Therefore, it is desirable for the connection region R1 to be small. However, in the case where the planar configurations of the multiple solar cells are different from each other, it is difficult to coat the photoelectric conversion layer every solar cell. For example, in the case where the planar configurations of the multiple solar cells are different from each other, patterning using a coating method such as bar coating, die coating, etc., may be difficult.

Conversely, in the method for manufacturing the solar cell module according to the embodiment, the narrow connection region R1 can be formed by setting the surface of the third lower intermediate layer 43 to be repellent to the liquid including the organic semiconductor.

FIG. 6 is a schematic plan view showing a photovoltaic power generation panel using the solar cell module according to the embodiment.

As shown in FIG. 6, the photovoltaic power generation panel 200 includes the multiple solar cell modules 110. The multiple solar cell modules 110 are arranged on the X-Y plane. In the example, one solar cell module 110 has a rectangular configuration in which one side is about 20 cm to 30 cm when projected onto the X-Y plane. Such a solar cell module 110 is arranged to be three modules in the X-axis direction and four modules in the Y-axis direction. Thereby, a photovoltaic power generation panel that is about 1 m by about 1.2 m is formed.

The multiple solar cells 80 are arranged on the substrate in one solar cell module 110. The configuration of the substrate 5 projected onto the X-Y plane is, for example, a rectangular configuration. In the example, the configurations of the solar cells 80 projected onto the X-Y plane are rectangular configurations extending along the Y-axis direction. The multiple solar cells 80 are arranged in the X-axis direction. For example, the multiple solar cells 80 are connected in series.

The planar configuration of the solar cell module 110 and the planar configuration of the photovoltaic power generation panel 200 are not limited to rectangular configurations and may be any configuration. The number of solar cells 80 may be any number corresponding to the size of the substrate 5, etc. A portion of the multiple solar cells 80 may be connected in parallel.

In such a photovoltaic power generation panel, the aperture ratio of the solar cell module 110 can be increased by setting the connection region R1 between the solar cells 80 to be small. Thereby, a photovoltaic power generation panel that has a high efficiency can be obtained.

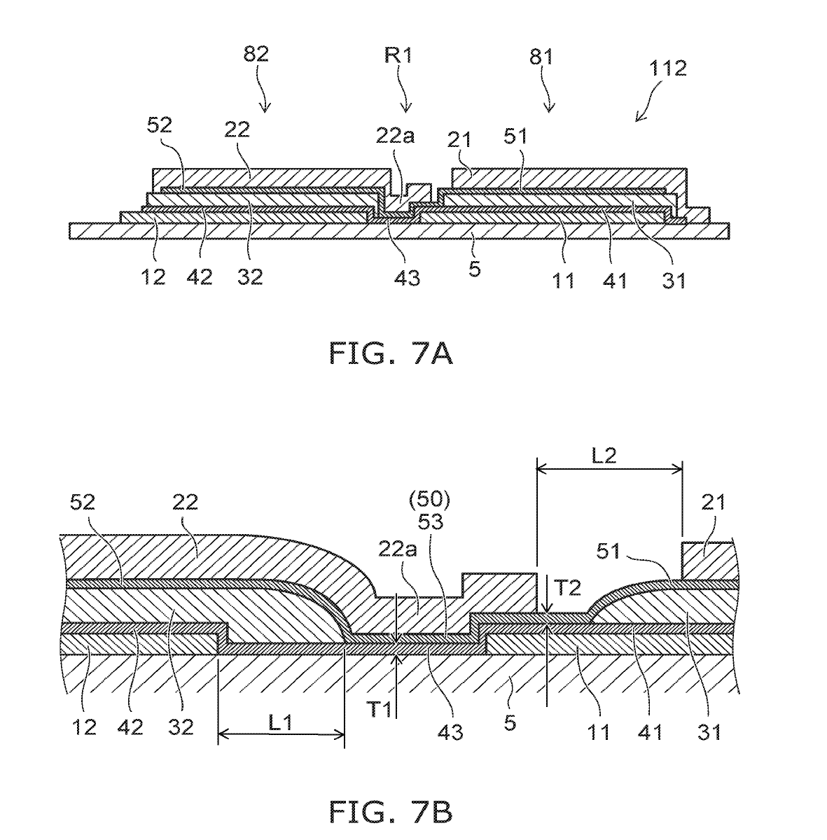

FIG. 7A and FIG. 7B are schematic cross-sectional views showing another solar cell module according to the embodiment.

As shown in FIG. 7A, the substrate 5, the first lower electrode 11, the first upper electrode 21, the first photoelectric conversion layer 31, the first lower intermediate layer 41, the first upper intermediate layer 51, the second lower electrode 12, the second upper electrode 22, the second photoelectric conversion layer 32, the second lower intermediate layer 42, the third lower intermediate layer 43, and the second upper intermediate layer 52 are provided in the solar cell module 112 according to the embodiment as well. A description similar to the description of the solar cell module 110 is applicable to these components.

FIG. 7B shows an enlarged region between the first photoelectric conversion layer 31 and the second photoelectric conversion layer 32 of FIG. 7A.

The solar cell module 112 further includes a third upper intermediate layer 53. The third upper intermediate layer 53 is provided between the third lower intermediate layer 43 and the first portion 22a.

The third upper intermediate layer 53 is continuous with the first upper intermediate layer 51 and the second upper intermediate layer 52. For example, each of the first to third upper intermediate layers 51 to 53 may be one portion included in one film (for example, an upper intermediate layer 50). In other words, the upper intermediate layer 50 includes a first upper region (the first upper intermediate layer 51), a second upper region (the second upper intermediate layer 52), and a third upper region (the third upper intermediate layer 53). The material and formation method of the third upper intermediate layer 53 are similar to the description of the first upper intermediate layer 51. For example, the third upper intermediate layer 53 includes the same material as the first upper intermediate layer 51 and includes the same material as the second upper intermediate layer 52.

In the solar cell module 112, the third upper intermediate layer 53 that is continuous with the first upper intermediate layer 51 and the second upper intermediate layer 52 is provided in the connection region R1. Thereby, the difference between the appearance of the first solar cell 81 and the appearance of the connection region R1 can be reduced. Thereby, the appearance of the solar cell module can be improved. For example, the decorative quality of the wristwatch can be improved by including the solar cell module 112 in the solar cell module for the wristwatch, etc.

It is desirable for the resistance value (the resistance value along the X-axis direction) of the third upper intermediate layer 53 to be sufficiently higher than the resistance value of the first portion 22a. It is desirable for the sheet resistance of the third upper intermediate layer 53 to be sufficiently higher than the sheet resistance of the first portion 22a. Thereby, even in the case where the third lower intermediate layer 43 includes the same material as the first upper intermediate layer 51 and the second upper intermediate layer 52, the occurrence of shorts between the first upper electrode 21 and the second upper electrode 22 can be suppressed. Thereby, the first solar cell 81 and the second solar cell 82 can be connected substantially in series.

On the other hand, in the case where the third upper intermediate layer 53 includes the same material as the first upper intermediate layer 51, it is desirable for the resistivity of the third upper intermediate layer 53 not to be too high because the first upper intermediate layer 51 functions as a hole transport layer.

For example, the resistance value of the third upper intermediate layer 53 is not less than 2×10⁵ times and not more than 2×10¹⁰ times the resistance value of the first portion 22a. For example, the sheet resistance value of the third upper intermediate layer 53 is not less than 2×10⁴Ω/□ and not more than 2×10⁹Ω/□. For example, the resistivity of the third upper intermediate layer 53 is not less than 1×10⁵ times and not more than 1×10¹⁰ times the resistivity of the first portion 22a. For example, a thickness T2 (the length of the film along the Z-axis direction) of the third upper intermediate layer 53 is not less than 10 nm and not more than 100 nm. A distance L2 along the X-axis direction between the first upper electrode 21 and the second upper electrode 22 is, for example, not less than 50 μm and not more than 250 μm.

By providing a third upper intermediate layer 53 such as that described above, the appearance of the solar cell module can be improved further.

According to the embodiment, a solar cell module having a good appearance can be provided.

In this specification, being “electrically connected” includes not only the case of being connected in direct contact but also the case of being connected via another conductive member, etc.

In this specification, “perpendicular” includes not only strict perpendicular but also, for example, the fluctuation due to manufacturing processes, etc.; and it is sufficient to be substantially perpendicular.

Hereinabove, embodiments of the invention are described with reference to specific examples. However, the embodiments of the invention are not limited to these specific examples. For example, one skilled in the art may similarly practice the invention by appropriately selecting specific configurations of components such as the substrate, the upper electrode, the lower electrode, the photoelectric conversion layer, the lower intermediate layer, the upper intermediate layer, etc., from known art; and such practice is within the scope of the invention to the extent that similar effects can be obtained.

Any two or more components of the specific examples may be combined within the extent of technical feasibility and are within the scope of the invention to the extent that the spirit of the invention is included.

All solar cell modules and methods for manufacturing solar cell modules practicable by an appropriate design modification by one skilled in the art based on the solar cell modules and the methods for manufacturing the solar cell modules described above as embodiments of the invention also are within the scope of the invention to the extent that the spirit of the invention is included.

Various modifications and alterations within the spirit of the invention will be readily apparent to those skilled in the art; and all such modifications and alterations should be seen as being within the scope of the invention.

Although several embodiments of the invention are described, these embodiments are presented as examples and are not intended to limit the scope of the invention. These novel embodiments may be implemented in other various forms; and various omissions, substitutions, and modifications can be performed without departing from the spirit of the invention. Such embodiments and their modifications are within the scope and spirit of the invention and are included in the invention described in the claims and their equivalents.

What is claimed is:

1. A solar cell module, comprising:
a substrate;
a first upper electrode;
a first lower electrode provided between the first upper electrode and the substrate;
a first photoelectric conversion layer provided between the first upper electrode and the first lower electrode, the first photoelectric conversion layer including an organic semiconductor;
a second upper electrode separated from the first upper electrode in a direction intersecting a first direction, the first direction being from the first lower electrode toward the first upper electrode;
a second lower electrode provided between the second upper electrode and the substrate;
a second photoelectric conversion layer provided between the second upper electrode and the second lower electrode, the second photoelectric conversion layer including an organic semiconductor; and
a lower intermediate layer,
the second upper electrode including a first portion provided between the first photoelectric conversion layer and the second photoelectric conversion layer in the direction intersecting the first direction,
the lower intermediate layer including
a first lower region disposed between the first photoelectric conversion layer and the first lower electrode,
a second lower region disposed between the second photoelectric conversion layer and the second lower electrode, and
a third lower region disposed between the first portion and the substrate.

2. The module according to claim 1, wherein the third lower region is continuous with the first lower region and the second lower region.

3. The module according to claim 1, wherein
the second photoelectric conversion layer includes an end portion in the intersecting direction positioned between the first lower electrode and the second lower electrode, and
a distance between the end portion and the second lower electrode is not less than 1000 times a thickness of the third lower region.

4. The module according to claim 1, wherein a resistance value along the intersecting direction of the first portion is lower than a resistance value along the intersecting direction of the third lower region.

5. The module according to claim 1, further comprising an upper intermediate layer including a first upper region, a second upper region and a third upper region,
the first upper region being provided between the first upper electrode and the first photoelectric conversion layer,
the second upper region being provided between the second upper electrode and the second photoelectric conversion layer,
the third upper region being provided between the first portion and the third lower region.

6. The module according to claim 5, wherein the third upper region is continuous with the first upper region and the second upper region.

7. The module according to claim 1, wherein the third lower region includes the same material as the first lower region and includes the same material as the second lower region.

8. The module according to claim 1, wherein the second upper electrode is electrically connected to the first lower electrode.

9. The module according to claim 8, wherein a thickness of the third lower region is not less than 5 nm and not more than 50 nm.

10. The module according to claim 9, wherein a resistivity of the third lower region is not less than 1×10⁵ times and not more than 1×10¹⁰ times a resistivity of the first portion.

11. The module according to claim 1, wherein the substrate, the first lower electrode, and the second lower electrode are light-transmissive.

12. The module according to claim 11, wherein the first lower electrode includes an oxide of at least one selected from indium, zinc, and tin.

13. The module according to claim 5, wherein
the first upper region is a hole transport layer, and
the first lower region is an electron transport layer.

14. The module according to claim 1, wherein the first photoelectric conversion layer includes an n-type organic semiconductor, and a p-type organic semiconductor having a bulk heterojunction with the n-type organic semiconductor.

15. A method for manufacturing a solar cell module, comprising:
a lower electrode formation process of forming a first lower electrode and a second lower electrode on a substrate, the second lower electrode being separated from the first lower electrode;
a lower intermediate layer formation process of forming a lower intermediate layer including a first lower region and a second lower region, the first lower region being formed on the first lower electrode, the second lower region being formed on the second lower electrode;
a processing process of modifying a surface state of the first lower region and a surface state of the second lower region;
a photoelectric conversion layer formation process of forming a first photoelectric conversion layer on the first lower region and forming a second photoelectric conversion layer on the second lower region, the first photoelectric conversion layer including an organic semiconductor, the second photoelectric conversion layer including an organic semiconductor; and
an upper electrode formation process of forming a first upper electrode on the first photoelectric conversion layer and forming a second upper electrode on the second photoelectric conversion layer.

16. The method according to claim 15, wherein
the lower intermediate layer further includes a third lower region, and
the lower intermediate layer formation process includes forming the third lower region between the first lower electrode and the second lower electrode.

17. The method according to claim 16, wherein the third lower region is continuous with the first lower region and the second lower region.

18. The method according to claim 16, wherein the third lower region includes the same material as the first lower region and includes the same material as the second lower region.

19. The method according to claim 15, wherein the photoelectric conversion layer formation process includes coating a liquid onto the first lower region and the second lower region, the liquid including an organic semiconductor.

20. The method according to claim 19, wherein the processing process includes modifying a wettability of a surface of the first lower region for the liquid and modifying a wettability of a surface of the second lower region for the liquid.
